(19) United States
(12) Patent Application Publication
(10) Pub. No.: US 2013/0312666 A1
(43) Pub. Date: Nov. 28, 2013

(54) APPARATUS FOR DEPOSITING THIN FILM

(71) Applicants: Yu-Chiu Shih, Taichung (TW); Hsiu-Po Liu, Taichung (TW)

(72) Inventors: Yu-Chiu Shih, Taichung (TW); Hsiu-Po Liu, Taichung (TW)

(73) Assignee: GCSOL TECH CO., LTD., TAICHUNG (TW)

(21) Appl. No.: 13/549,929

(22) Filed: Jul. 16, 2012

(30) Foreign Application Priority Data
May 22, 2012 (TW) 101118224

(51) Int. Cl. C23C 16/458

(52) U.S. Cl. 118/728; 118/715

(57) ABSTRACT

An apparatus for depositing a thin film basically consists of a base, two lateral boards and two sealing members to form a closed chamber therein. Each lateral board is provided with a substrate on an inner side thereof. Each substrate has a side in contact with a chemical solution in the chamber to deposit a thin film on the side of the substrate through a chemical reaction.

### BACKGROUND OF THE INVENTION

1. Field of the Invention

The present invention relates generally to a thin film deposition apparatus, and an apparatus for depositing a thin film on single side of a substrate.

2. Description of the Related Art

In many fields, especially in the field of semiconductor manufacture, thin film deposition technique is frequently used to form thin films on specific objects, and usually is on a substrate. In a conventional method of thin film deposition, the substrate is mounted on a frame, and then the frame is put in a container filled with chemical solution to deposit thin films on both sides of the substrate through a chemical reaction under a controlled temperature and time. However, it has the following drawbacks:

1. The conventional depositing method cannot deposit a thin film on single side of the substrate only. In order to deposit a thin film on single side of the substrate, it has to remove the thin film from one side of the substrate after the conventional depositing method. It is very clear that the conventional method of depositing the thin film on single side of the substrate takes long time and costs much.

2. The conventional depositing method deposits thin films on both sides of the substrate, and the thin films are the same. It cannot make a substrate with different thin films.

3. The container must be large enough to receive both the frame and the substrate. Therefore, more chemical solution is needed, and the cost is raised consequently. Furthermore, it takes longer time to deposit the thin film.

### SUMMARY OF THE INVENTION

The primary objective of the present invention is to provide an apparatus for depositing a thin film on single side of a substrate.

According to the objective of the present invention, the present invention provides an apparatus for depositing a thin film on a substrate, including a base, two lateral boards, and two sealing members. The base includes a frame, and the frame has an opening which is open at a left side and a right side of the frame and a bore communicated with the opening. The lateral boards are fixed to the right side and the left side of the frame to close opposite ends of the opening whereby a chamber is formed in the frame. A substrate is provided on an inner side of the lateral board so that a side of the substrate is in the chamber. The sealing members respectively are between the frame and the lateral boards and surround the opening.

In an embodiment, the at least one of the lateral board is provided with a clip slot to engage the substrate. In an embodiment, the lateral board with the substrate has an opening and at least a protrusion surrounding the opening. The protrusion and the lateral board form the clip slot. The frame is provided with recesses respectively to engage the protrusions of the lateral board.

In an embodiment, the frame respectively is provided with a slot on the left side and the right side to receive the sealing members; the slots surround the opening; and the sealing member presses the substrate.

In an embodiment, the apparatus further includes a device for securing the substrates on the frame. In an embodiment, the device includes at least a standard bore on the frame which is open at the left side and the right side, at least a positioning bore on the lateral boards, and at least a pin inserted into the standard bore and the positioning bores. The device further includes two standard protrusions on the left side and the right side of the frame, on which the lateral boards are rested.

In an embodiment, the bore is on a top side of the frame.

In an embodiment, the frame further includes at least an air bore on a bottom side thereof; and the air bore has an end communicated with the opening and the other end connected to an air compressor.

In an embodiment, the apparatus further includes at least a temperature controller, wherein the lateral board has the substrate on the inner side and the temperature on an outer side.

In an embodiment, the apparatus further includes at least a plug connected to the bore of the frame to close the bore.

Therefore, the apparatus of the present invention may deposit a thin film on single side of an object (substrate). It may have a short process and a high production efficiency, and furthermore, it may speed up the depositing reaction.

### BRIEF DESCRIPTION OF THE DRAWINGS

FIG. 1 is an exploded view of a first preferred embodiment of the present invention;

FIG. 2 is a perspective view of the first preferred embodiment of the present invention;

FIG. 3 is a sectional view in the 3-3 line of FIG. 2;

FIG. 4 is a sectional view in the 4-4 line of FIG. 3;

FIG. 5 is a perspective view of a second preferred embodiment of the present invention;

FIG. 6 is a perspective view of a third preferred embodiment of the present invention;

FIG. 7 is a perspective view of a fourth preferred embodiment of the present invention;

FIG. 8 is a perspective view of a fifth preferred embodiment of the present invention;

FIG. 9 is a perspective view of a sixth preferred embodiment of the present invention; and

FIG. 10 is a perspective view of a seventh preferred embodiment of the present invention.

### DETAILED DESCRIPTION OF THE INVENTION

The detailed description and technical contents of the present invention will be explained with reference to the accompanying drawings. However, the drawings are illustrative only but not used to limit the present invention.

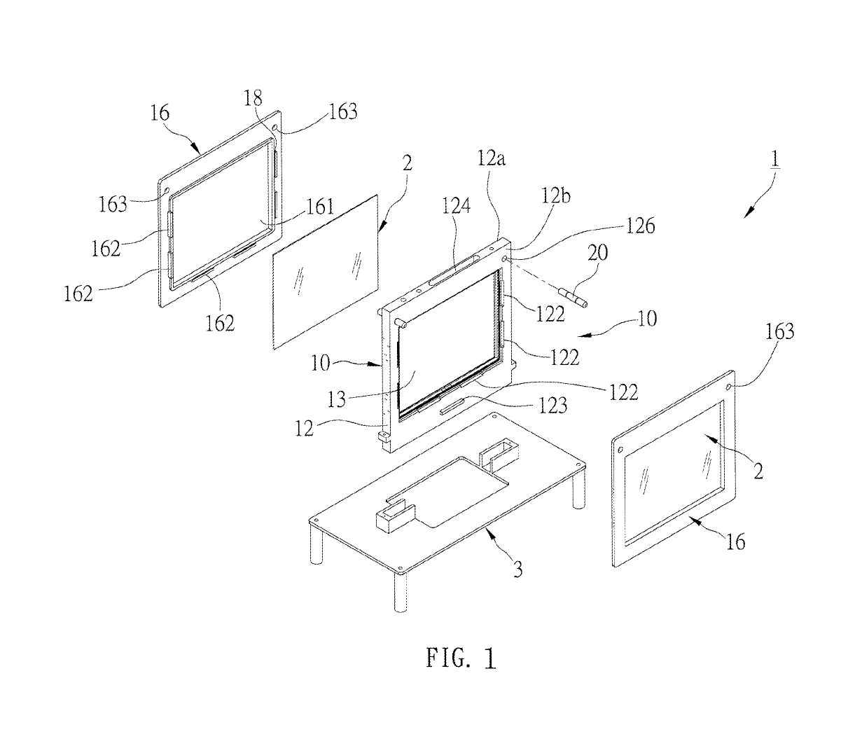

As shown in FIG. 1 to FIG. 3, an apparatus 1 for depositing thin film of the first preferred embodiment of the present invention includes a base 10, two sealing members 14, and two lateral boards 16.

The base 10 includes a rectangle frame 12, and the frame 12 has an opening 13. A left side 12a and a right side 12b of the frame 12 are symmetrical, so we only describe the right side 12b hereafter.

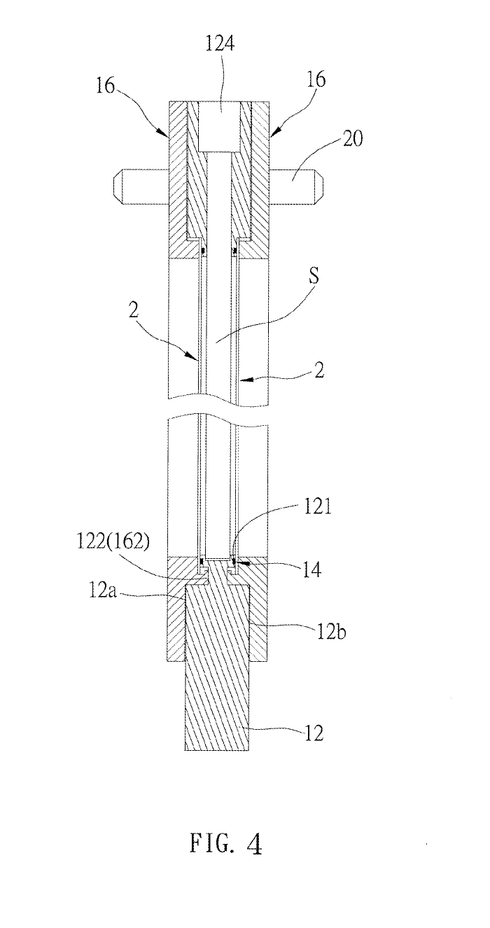

As shown in FIG. 1 and FIG. 4, on the right side 12b of the frame 12, it has a slot 121 surrounding the opening 13 to receive the sealing member 14. The sealing members 14 are flexible. A thickness of the sealing member 14 is greater than a depth of the slot 121 so that the sealing member 14 has a portion out of the slot 121. On the right side 12b, the frame 12 further has a plurality of recesses 122 surrounding the opening 13 and a transverse standard protrusion 123 under the opening 13.

The frame 12 has a bore 124 at a top side 12c, an outlet 123 at a bottom side 12d thereof, and two standard bores 126 extending from the left side 13a to the right side 12b. The bore 124 and the outlet 125 respectively are communicated with the opening 13.

Each lateral board 16 has a rectangular opening 161, a plurality of protrusions 162, and two positioning bores 163. As shown in FIG. 1, the protrusions 162 surround the opening 161 in a U-shaped layout, and it has two protrusions 162 at each side of the opening 161 except the top side. Each protrusion 162 is an L-shaped member. The protrusions 162 form a clip slot 18 on the lateral board 16 to engage a substrate 2. The substrate 2 is held by the L-shaped protrusions 162 to close the opening 161 of the lateral board 16.

The lateral board 16 rests on the standard protrusion 123, the positioning bores 163 of the lateral board 16 respectively are aligned with the standard bores 126 of the frame 12, and the protrusions 162 respectively engages the recesses 122 so that pins 20 are inserted into the positioning bores 163 of the lateral board 16 and the standard bores 126 of the frame 12 to fix the lateral boards 16 to the left side 12a and the right side 12b of the frame 12. The sealing members 14 respectively are between the substrates 2 and the lateral boards 16 to seal the opening 13 of the base and form a closed chamber S. In other words, the chamber S is within the substrates 2 and the frame 12, and the sealing members 14 provide the chamber S an airtight condition.

The positioning bores 163, the standard bores 126, the pins 20 and the standard protrusions 123 are the elements of a positioning device of the present invention to assemble the frame 12 and the lateral boards 14 in a fast way. It may provide bolts and nut to secure the frame 12 and the lateral boards 14, or it may use a clamping member to press the lateral boards 14 on the frame 12 and then to deform the sealing member 14.

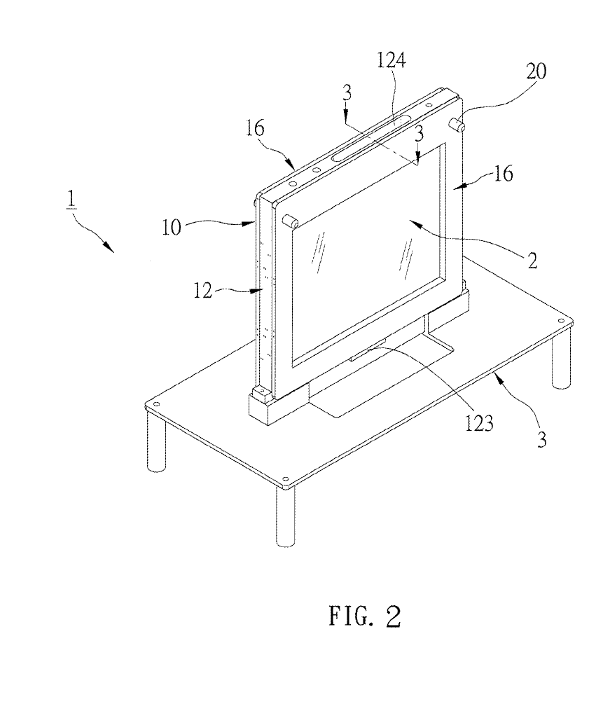

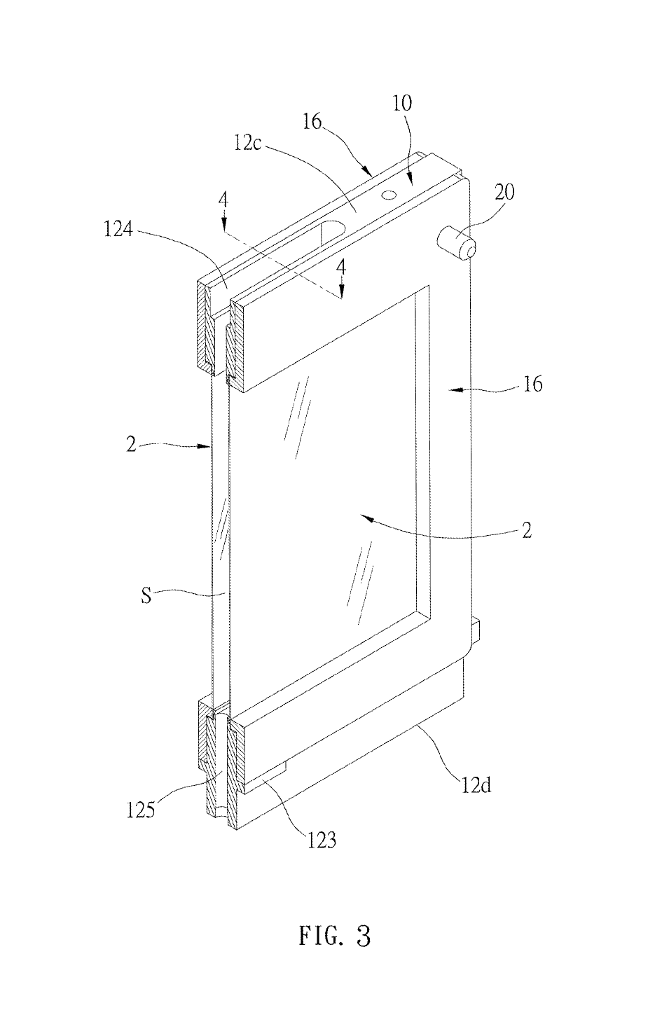

As shown in FIG. 2 and FIG. 3, the apparatus 1 is mounted on a holder 3 to deposit thin films on the substrate 2. The outlet 125 is normally closed. Chemical solution is poured into the chamber S via the bore 124. Inner sides of the substrates 2 are in contact with the chemical solution to deposit thin films on the substrates 2 through a chemical reaction under a controlled time and temperature. After the depositing process is completed, the outlet 125 is opened to drain the chemical solution out, and then we will get the substrates 2 with the thin film on single side thereof. The chemical solution will be drained to a solution recycling system (not shown).

The apparatus 1 of the present embodiment may be assembled in an easy way to deposit a thin film on single side of the substrate 2. It has no step of removing the thin film from on the substrate so that the apparatus 1 has a short process to increase the production efficiency. Less chemical solution is needed in the apparatus 1 of the present embodiment so that the cost is reduced. A distance between the substrates 2 on the lateral boards 16 is short therefore it will have a short reaction time to speed up the depositing process.

Above description are the structure, operation and function of the apparatus 1 of the first preferred embodiment. It has to be mentioned that a specific stirring device may be put into the chamber S through the bore 124 to stir the chemical solution, and this will make an even thin film on the substrate. The stirring device may just a stick to stir or reciprocate up-and-down.

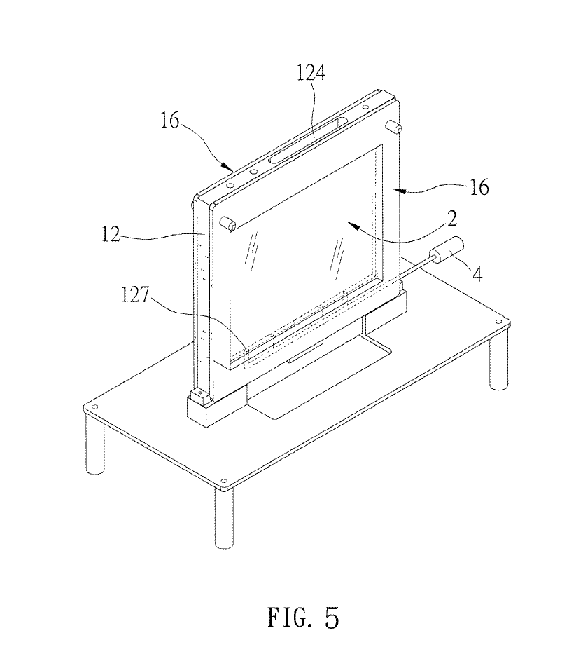

FIG. 5 shows an apparatus for depositing thin film of the second preferred embodiment, in which the frame 12 is provided with a plurality of air bores 172 at the bottom side thereof. The air bores 172 are communicated with the chamber S and are connected to an air compressor 4 to supply air into the chamber and form air bubbles in the chemical solution. This may generate turbulence in the chemical solution to achieve the same purpose as above. The air compressor 4 may be replaced by a circulating system (not shown).

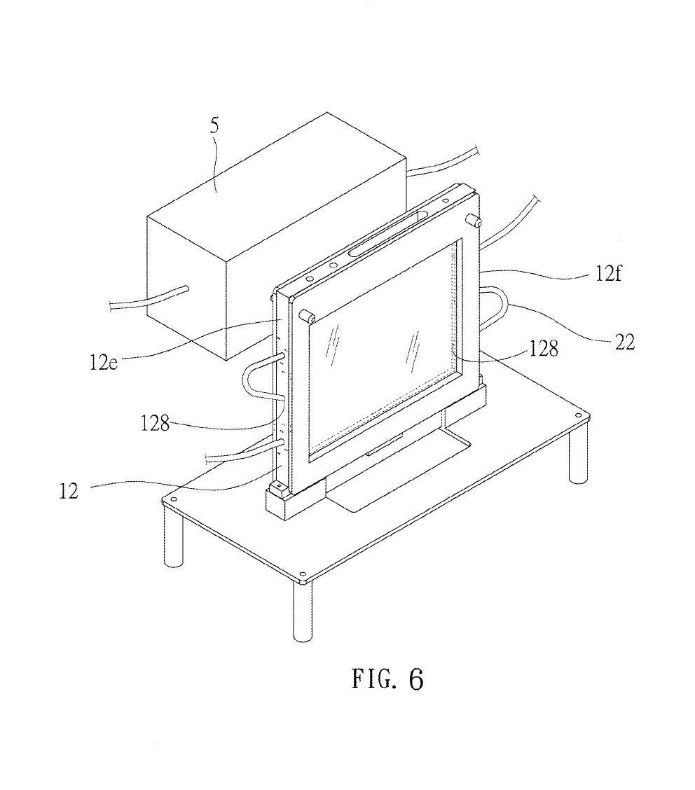

FIG. 6 shows an apparatus for depositing thin film of the third preferred embodiment, in which the frame 12 is provided with a plurality of bores 128 extending from a front side 12e to a rear side 12f. The bores 128 are connected to a forced circulating system 5 though hoses 22. The forced circulating system 5 provides compressed chemical solutions to the chamber S through the hoses 32. The chemical solution keeps circulation in the chemical reaction to achieve the same purpose of above.

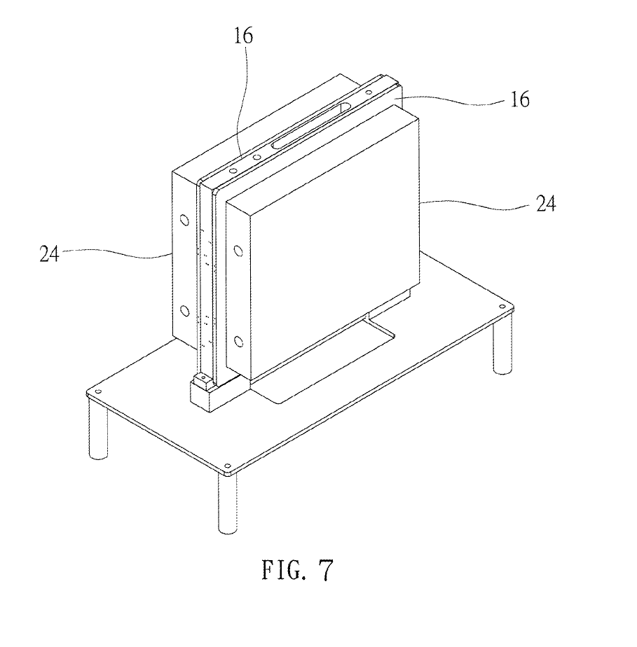

As shown in FIG. 7, an apparatus of the fourth preferred embodiment of the present invention further includes two temperature controllers 24 on outer sides of the lateral boards 16 or on the substrates 2 to control the temperature of the chemical reaction in the chamber. The temperature controllers 24 may provide hot air or cold air to the chamber to change the temperature therein and to speed up the reaction.

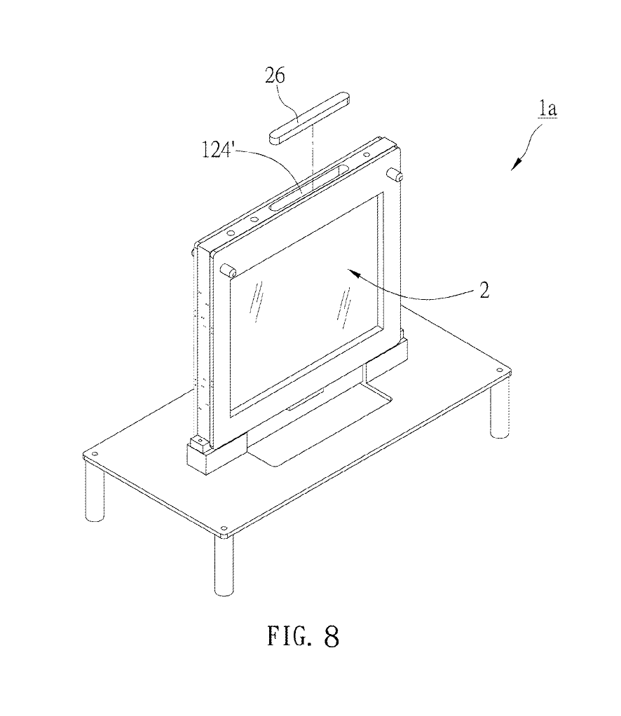

In above embodiments, chemical solution is used to be the reaction medium for depositing the thin film. In practice, gas may be the reaction medium also. As shown in FIG. 8, an apparatus 1a of the fifth preferred embodiment of the present invention provides a bore 124′ on the frame 12 to supply reaction gas into the chamber S. A plug 26 is squeezed into the bore 124′ to seal the bore 124′. Therefore, a proper chemical reaction is proceeding in the chamber S to deposit thin film on the substrate 2.

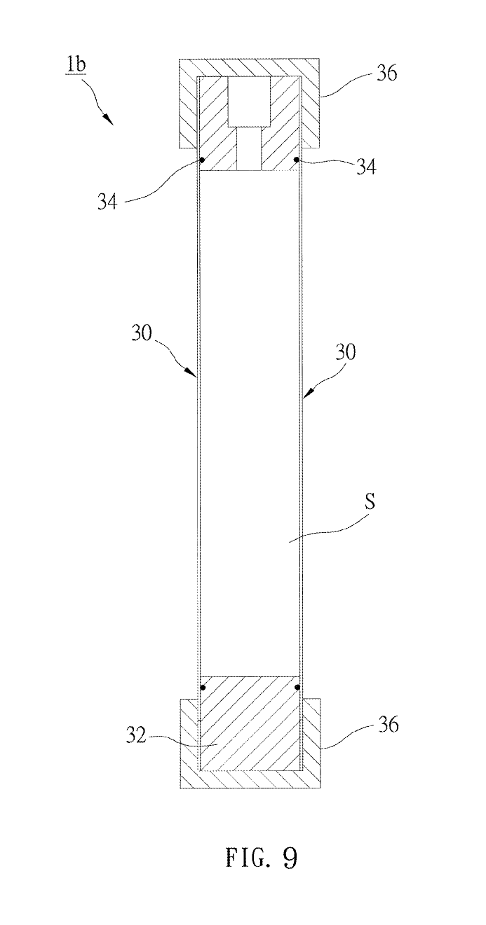

FIG. 9 shows an apparatus 1b for depositing thin film of the sixth preferred embodiment, which has no lateral board. The apparatus 1b provides two substrates 30 on opposite sides of a base 32 to form a closed chamber S in the base 32. The apparatus 1b has the same function as above to deposit a thin film on single side of each substrate 30. Two sealing members 34 are between the substrates 30 and the base 32, and a device holds the substrates 30 and the base 32 to keep the airtight condition of the chamber S. In practice, the device may be two clamping devices 36 provided on top and bottom sides of the base 32 to clamp the substrates 30 and the base 32.

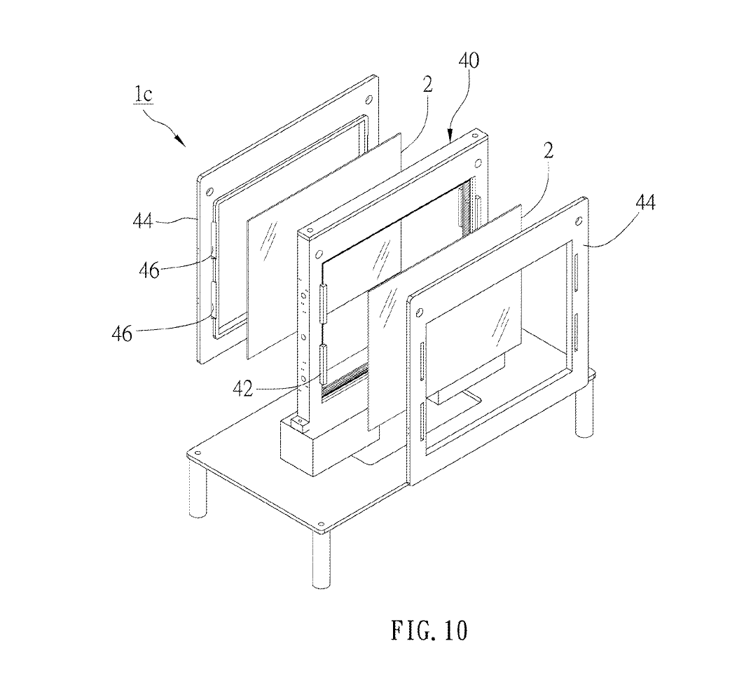

FIG. 10 shows an apparatus 1c for depositing thin film of the seventh preferred embodiment, in which a frame 40 is provided with a plurality of L-shaped protrusions 42 on both sides thereof to form a clip slot on each side thereof. Substrates 2 may be inserted into the clip slots to be secured on the frame 40, and sealing members (not shown) are put between the substrate 2 and the frame 40 to form a closed chamber in the frame 40. Chemical solution is poured into the chamber for the reaction to deposit a thin film on single side of each substrate 2.

The description above is a few preferred embodiments of the present invention and the equivalence of the present invention is still in the scope of claim construction of the present invention.

What is claimed is:

1. An apparatus for depositing a thin film on a substrate, comprising:
a base including a frame, wherein the frame has an opening which is open at a left side and a right side of the frame and a bore communicated with the opening;
two lateral boards fixed to the right side and the left side of the frame to close opposite ends of the opening whereby a chamber is formed in the frame, wherein a substrate is provided on an inner side of the lateral board so that a side of the substrate is in the chamber; and
two sealing members respectively between the frame and the lateral boards and surrounding the opening.

2. The apparatus as defined in claim 1, wherein the lateral board is provided with a plurality of protrusions on the inner side to form a clip slot, and the substrate engages the clip slot to be held by the protrusions.

3. The apparatus as defined in claim 2, wherein the frame is provided with recesses respectively to engage the protrusions of the lateral board.

4. The apparatus as defined in claim 1, wherein the frame is provided with a plurality of protrusions on the inner side to form a clip slot, and the substrate engages the clip slot to be held by the protrusion.

5. The apparatus as defined in claim 4, wherein the lateral board is provided with recesses respectively to engage the protrusions of the frame.

6. The apparatus as defined in claim 1, wherein the frame respectively is provided with a slot on the left side and the right side to receive the sealing members; the slots surround the opening; and the sealing member presses the substrate.

7. The apparatus as defined in claim 1 further comprising a device for connecting the base and the lateral board.

8. The apparatus as defined in claim 7, wherein the device includes at least a standard bore on the frame which is open at the left side and the right side, at least a positioning bore on the lateral boards, and at least a pin inserted into the standard bore and the positioning bores.

9. The apparatus as defined in claim 8, wherein the device further includes two standard protrusions on the left side and the right side of the frame, on which the lateral boards are rested.

10. The apparatus as defined in claim 1, wherein the bore is on a top side of the frame.

11. The apparatus as defined in claim 1, wherein the frame further includes at least an air bore on a bottom side thereof; and the air bore has an end communicated with the opening and the other end connected to an air compressor.

12. The apparatus as defined in claim 1, wherein the frame further includes at least an air bore on a bottom side thereof; and the air bore has an end communicated with the opening and the other end connected to a circulating system.

13. The apparatus as defined in claim 1, wherein the frame further includes an outlet on a bottom side thereof; and the outlet is connected to a solution recycling system.

14. The apparatus as defined in claim 1, wherein the frame has a plurality of the bores on a front side and a rear side of the frame; each of the bores has an end communicated with the opening and the other end connected to a forced circulating system.

15. The apparatus as defined in claim 10, further comprising at least a temperature controller, wherein the lateral board has the substrate on the inner side and the temperature on an outer side.

16. The apparatus as defined in claim 10, further comprising at least a plug connected to the bore of the frame to close the bore.

17. An apparatus for depositing a thin film on a substrate, comprising:
a base including a frame, wherein the frame has an opening which is open at a left side and a right side of the frame and a bore communicated with the opening;
two substrates provided on the right side and the left side of the frame to close opposite ends of the opening whereby a chamber is formed in the frame;
two sealing members respectively between the frame and the lateral boards and surrounding the opening; and
means for securing the substrates on the frame.

18. The apparatus as defined in claim 17, wherein the means includes a clamping device pressing the substrates on the frame to deform the sealing members.

19. The apparatus as defined in claim 17, wherein the bore is on a top side of the frame.

20. The apparatus as defined in claim 17, wherein the frame further includes at least an air bore on a bottom side thereof; and the air bore has an end communicated with the opening and the other end connected to an air compressor.

21. The apparatus as defined in claim 17, wherein the frame further includes at least an air bore on a bottom side thereof; and the air bore has an end communicated with the opening and the other end connected to a circulating system.

22. The apparatus as defined in claim 17, wherein the frame further includes an outlet on a bottom side thereof; and the outlet is connected to a solution recycling system.

23. The apparatus as defined in claim 17, wherein the frame has a plurality of the bores on a front side and a rear side of the frame; and each of the bores has an end communicated with the opening and the other end connected to a forced circulating system.

24. The apparatus as defined in claim 17, further comprising at least a temperature controller, wherein the lateral board has the substrate on the inner side and the temperature on an outer side.

25. The apparatus as defined in claim 17, further comprising at least a plug connected to the bore of the frame to close the bore.
